(19) United States
(12) Patent Application Publication
(10) Pub. No.: US 2008/0258365 A1
(43) Pub. Date: Oct. 23, 2008

(54) Vibration Damper for Isolator

(75) Inventors: Henricus Johannes Adrianus Van De Sande, Eindhoven (NL); Hubert Gerard Jean Joseph Amaury Vroomen, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/568,989

(22) PCT Filed: May 9, 2005
(86) PCT No.: PCT/IB2005/051503

§ 371 Date: Nov. 13, 2006

(30) Foreign Application Priority Data
May 14, 2004 (EP) 04102120.5

(51) Int. Cl. G03F 7/20; F16F 15/00

(52) U.S. Cl. 267/140.14

(57) ABSTRACT

A system for use in for example the production of semiconductors comprises a chamber (10) having a sealed inner space (11), such as a vacuum chamber. A heavy mass (14), such as a table, is arranged within the vacuum chamber and is supported or carried by one or more vibration dampers or isolators (15). Each vibration isolator comprises a hollow or tubular member (18) having an open inner end portion, which extends into the sealed space of the chamber (10). A support structure (21) is arranged at the inner end of the hollow member for supporting the mass or table (14). The opposite ends of a bellows (24) are sealingly connected to the hollow member (18) and the support structure (21), respectively, so as to seal the inner space (26) of the hollow member (18) from the inner space (11) of the chamber (10). A surface part of the support structure is exposed to a to a gas pressure different from that of the sealed inner space of the chamber, so as to at least partly balance the weight of the support structure (21) and the mass or payload (14) supported thereby.

The present invention relates to a system of the type having a sealed chamber with a selected atmosphere, such as vacuum, in which processing and/or examination of an object or a work piece should take place with very high accuracy. In such systems it is important to reduce or counteract “noise”, which means external or internal influences causing vibrations of the payload or work piece, as much as possible and to be able to adjust the position of the object.

EP-A2-1 148 389 discloses a lithographic projection apparatus of the above type having a vacuum chamber, in which a pneumatic gravity compensator supporting an object table is arranged. The piston of the pneumatic gravity compensator is connected to the object table by a partially flexible rod. In this known system the gravity compensator arranged totally inside the vacuum chamber and is therefore not easily accessible. Furthermore, evacuating means for evacuating gas escaping through a gap between the movable member or piston and a cylinder surface are needed. The above European patent also discloses a (differentially pumped) air bearing, which is used for the piston function. Such air bearings are complex and expensive, which is also a disadvantage of this known design.

It is an object of the present invention to overcome these disadvantages of the prior art.

The present invention provides a system of the above type, wherein these disadvantages are overcome in a very simple manner. Thus, the present invention provides a system comprising a chamber defining a sealed inner space and at least one vibration damper or isolator for supporting or carrying a mass or payload arranged within said space, said vibration damper comprising a hollow member having an open inner end portion extending into the sealed space of the chamber, a support structure for supporting or carrying said mass, a bellows having its opposite ends sealingly connected to the hollow member and the support structure, respectively, so as to seal the inner space of the hollow member from the inner space of the chamber, andmeans for exposing a surface part of the support structure to a gas pressure different from that of the sealed inner space of the chamber, so as to at least partly balance the weight of the support structure and said mass supported or carried thereby. The support structure is preferably arranged at the inner end portion of the hollow member and connected thereto by means of the bellows.

Parts and accessories arranged within the inner space of the hollow member are not exposed to the atmosphere of the sealed inner space, which is also not contaminated by outgases from such accessories. Because the inner space of the hollow member may be made accessible from outside, parts arranged therein are easily accessible for inspection and replacement. Furthermore, escape of air or another gas from the inner space of the hollow member into the sealed space of the chamber is not possible, because these spaces are hermetically sealed from each other by the bellows. The position of the mass or payload, such as a table carrying an object to be processed or examined, in relation to an adjacent chamber wall may be adjusted by changing the difference in pressure between the inner space of the chamber and the inner space of the hollow member. During normal operation, however, the pressure in the inner space of the hollow member is normally kept constant.

The hollow member may, for example, extend upwardly through a bottom wall of said chamber, and the support structure may then extend upwardly from the hollow member, or the hollow member may extend downwards from a top wall of the chamber and the support structure may then depend from the hollow member. In the first case the gas pressure within the hollow member is usually kept higher than within the chamber, and the lifting force applied to the mass or payload by the pressure difference may then be increased by means of a mechanical spring, if necessary. In the latter case the gas pressure within the hollow member is usually kept lower than within the sealed inner space of the chamber.

The system according to the invention may be used in connection with any of a great variety of treatments, examinations or processes including, but not limited to E-beam lithography, electron microscopy, mask alignment, micro lithography, micro machining, micro positioning, optical metrology machine vision, video microscopy, wafer probing, scanning electron microscopes, scanning tunnelling microscopes, transmission electron microscopes, magnetic resonance imaging, micro electromechanical systems, surface profilers, interferometry and other high resolution equipment. It should be understood that the atmosphere within the sealed space of the chamber is chosen depending on the actual application. Thus, the chamber may be a vacuum chamber or may contain air at a sub atmospheric pressure. For other applications an atmosphere of nitrogen or another gas, such as hydrogen, at super atmospheric, atmospheric or sub atmospheric pressure may be selected.

According to a further aspect, the present invention also provides a vibration damper or isolator for use in a system as described above, said vibration isolator comprising a hollow member having an end portion for extending into the sealed space of the chamber, a support structure arranged at said end portion of the hollow member for supporting said mass or payload, and a bellows having its opposite ends sealingly connected to the hollow member and the support structure, respectively.

As mentioned above, such vibration damper or isolator allows an easy inspection and replacement of the inner space of parts and accessories arranged within the inner space of the hollow member and does not involve any risk that air or another gas may escape from the inner space of the hollow member into the sealed space of the chamber.

The bellows, which is usually substantially tubular or annular may have any desired cross-sectional shape, such as circular, elliptical or rectangular, and may be made from any suitable material, such as thin sheet metal, rubber or plastics material. Preferably, however, the bellows should be a type allowing mutual movement of its opposite ends in the axial direction as well as a mutual translational movement in any radial direction of the bellows, which means in all three directions of a co-ordinate system having its z-axis coinciding with the longitudinal axis of the bellows. The bellows also preferably allows restricted rotational movements around any radially extending axis in a cross-sectional plane of the bellows. The bellows in itself may then constitute a passive vibration damper depressing vibration transfer from the hollow member to the support structure in such directions. A desired flexibility of the bellows may be obtained by suitably combining choices of material, wall thickness, size and shape of cross-section, corrugation shape and axial length of the bellows. However, material and wall thickness should preferably be chosen not only so as to keep transmission of vibrations between the hollow member and the support structure at a minimum, but also so as to prevent gas from penetrating through the wall of the bellows.

In a preferred embodiment the support structure comprises a base member, to which the bellows is connected, and an mass support member, which is supported by the base member via spring members allowing restricted rotational movement thereof in relation to the base member. Preferably, the spring members also allows other movements of the mass support member relative to the base member not allowed by the bellows. This means that the vibration damper can depress transfer of vibrations not only in all directions x, y, z of a co-ordinate system having its z-axis extending along the longitudinal axis of the bellows, but also rotational vibrations around such z-axis as well as any other kind of vibrations. The spring members may, for example, comprise leaf springs, and the planes of the leaf springs may, for example, extend in radial planes including the said z-axis.

As described above, the vibration damper or isolator according to the invention may be a passive damper. Preferably, however the damper or isolator is an active vibration isolator. Therefore, the vibration isolator according to the invention advantageously further comprises an active electronic vibration isolation circuit for assisting in counteracting vibrational movements of the mass or payload supported by the support structure. Such active damping circuits are well-known in the art, vide for example U.S. Pat. No. 4,796,873. The electronic vibration damping circuit may comprise one or more actuators and/or sensors, and they are preferably arranged inside the hollow member, where they are protected and easily accessible for inspection, adjustment and replacement. Other accessories, such as cabling and possible cooling means may also be arranged in the inner space of the hollow member, whereby it is prevented that possible outgasing from such items penetrates into the sealed inner space, of the chamber.

In a presently preferred embodiment a lower abutment surface defined by the bottom surface of the support structure may co-operate with an upper abutment surface defined by the hollow member, so as to limit axial or other relative movement of the support structure. However, under normal operation these abutment surfaces do not come into contact. Similar stops may be formed on the base member and the mass support member, respectively, of the support structure so as to limit mutual rotational movement of these members.

In order to allow use of a bellows of a desired length without prolonging the total length of the damper or isolator correspondingly at least part of the length of the bellows may extend along and adjacent to a length of a peripheral inner or outer surface of the hollow member.

These and other aspects of the invention will be apparent from and elucidated with reference to the embodiment described hereinafter. In the drawings

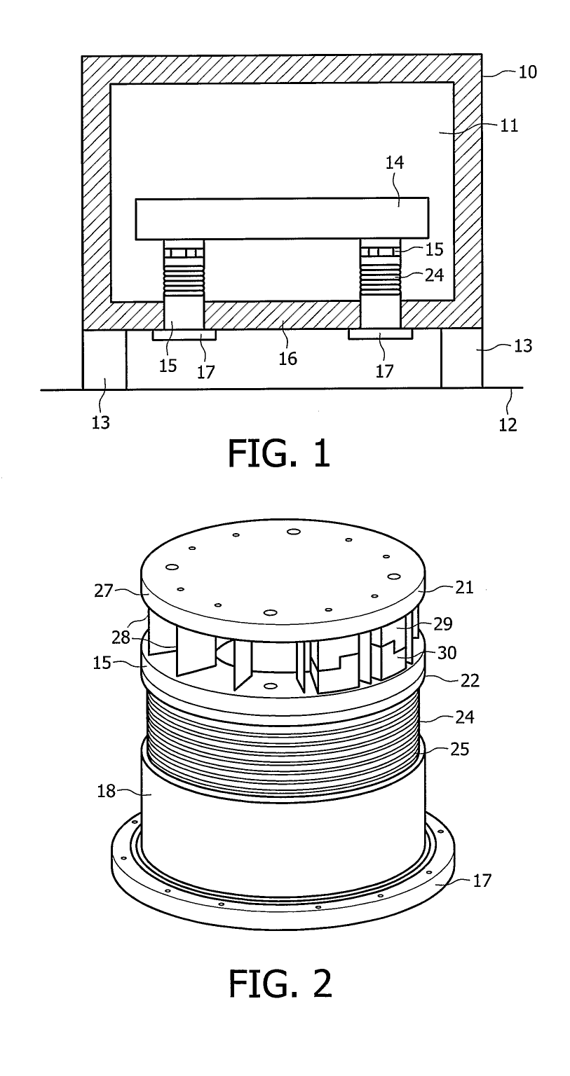

FIG. 1 is a diagrammatic sectional view of an embodiment of the system according to the invention,

FIG. 2 is a perspective view of a vibration isolator according to the invention shown in an enlarged scale,

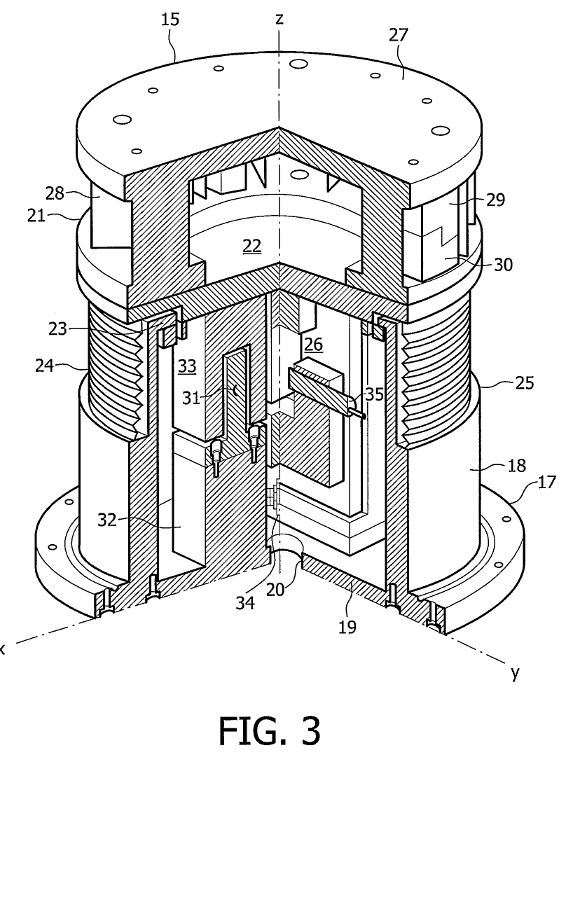

FIG. 3 is a perspective and partially sectional view of the isolation isolator shown in FIG. 2, and

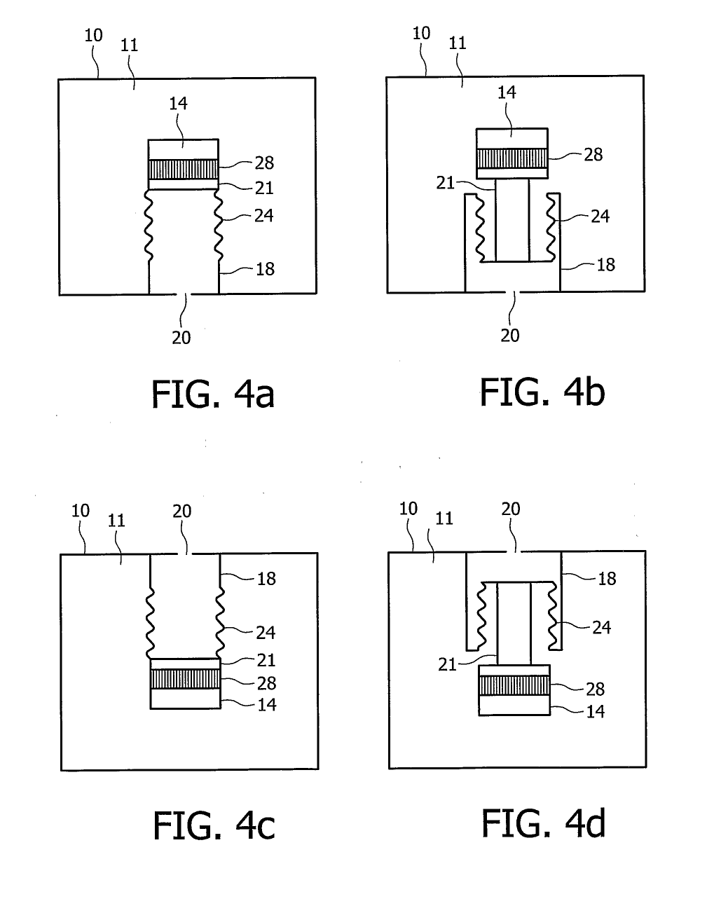

FIG. 4 diagrammatically illustrates various ways in which the mass or payload may be supported or carried by the hollow member.

FIG. 1 shows a processing system comprising a chamber 10, which defines therein a sealed inner space 11 with a predetermined atmosphere. The chamber 10 is supported by a ground or floor surface 12 via foot members 13. A mass or payload 14, such as a table and one or more objects or items (not shown) supported thereby, is arranged within the space 11 and is supported by a number (preferably at least three) of active vibration isolators 15. Each isolator 15 extends through an opening in the bottom wall 16 of the chamber 10 and has an outer annular flange 17, which is in sealing engagement with the bottom surface of the bottom wall of the processing chamber 10. The table 14 may, for example, carry a silicon wafer (not shown) being exposed to a lithography process in connection with the production of semiconductors.

FIGS. 2 and 3 illustrate one of the vibration isolators 15 shown in FIG. 1 in greater detail. The vibration isolator 15 comprises a hollow, substantially tubular member 18 having the annular flange 17 arranged at its outer end, which is closed by a bottom wall 19. This bottom wall, which may be formed integrally with or be releasably connected to the tubular member 18, has an inlet opening 20 for air or gas with a constant or variable, controlled pressure. The inner end opening of the tubular member 18 is covered by a separate support structure 21 including a plate-like base member 22. A radially inwardly extending annular flange 23 is received in a corresponding annular recess formed at the periphery of the base member 22 so as to allow minor relative axial and radial movements between the tubular member 18 and the base member 22 as well as minor rotational movements around the x-axis and y-axis (vide FIG. 3).

An upper length of the tubular member 18 has a reduced outer diameter so as to form an outer, annular recess, which receives an annular bellows 24, preferably made from sheet metal or plastics material. The axially opposite ends of the bellows are sealingly connected to an annular shoulder 25 formed on the tubular member 18 and to the bottom side of the base member 22, respectively, whereby the inner space 26 of the tubular member 18 is sealed from the inner space 11 of the chamber 10, when the isolator 15 is mounted in the chamber 10 as shown in FIG. 1.

The support structure 21 further comprises a supporting member 27, which is connected to and supports the table or mass 14. The plate-like base member 22 and the object supporting member 27 are interconnected via a plurality of leaf springs 28. Each of the leaf springs, which are arranged in a circular array, defines a radial plane including the longitudinal axis of the isolator 15. The leaf springs 28 have a flexibility so as to allow minor rotational movements of the supporting member 27 about the longitudinal axis z (FIG. 3) of the isolator 15 in relation to the base member 22. The maximum rotational movement of the supporting member 27 in relation to the base member 22 is determined by stop projections 29 extending downwards from the supporting member 27 and corresponding stop projections 30 extending upwardly from the base member 22. Each pair of stop projections 29, 30 has oppositely positioned complementary shaped, step-like stop surfaces. These complementary shaped stop surfaces are out of engagement during normal operation of the isolators 15, but come into abutting engagement in case of undue relative rotational movement of the members 22 and 27.

As mentioned above, the structure according to the present invention renders it possible to arrange various kinds of accessories within the inner space 26 of the tubular member 18 out of contact with the vacuum or another atmosphere of the inner space 11 of the processing chamber 10. Such accessories may, for example, comprise a vertically arranged actuator 31, such as a Lorenz actuator. The actuator 31 is arranged between an upright extending upwardly from the bottom wall 19 and a projection 33 depending from the base member 22 so that the actuator may provide axial forces between the tubular member 18 and the support structure 21. A similar actuator, not shown, may be tangentially or radially oriented. The function of the actuators may in a manner known per se be controlled by a control circuit, not shown, receiving input signals from position and/or velocity sensors 34 and 35. Geophones and other devices known in connection with active vibration isolation may also be added, if desired. All or most of the actuators and sensors and other electronic equipment is arranged outside the process chamber 10 and well protected inside the hollow member, which saves costs.

FIG. 4 diagrammatically illustrates various ways in which the mass or payload 14 may be supported by the tubular member 18 via the bellows 24 and the support structure 21. in FIG. 4a the tubular member 18 extends upwardly from the bottom wall 16 of the chamber 10, and the bellows 24, which supports the mass 14, forms a continuation of the tubular member. In FIG. 4a the gas pressure within the tubular member 18 preferably substantially exceeds the pressure in the inner space 11 of the chamber 10.

FIG. 4b mainly corresponds to FIG. 4a apart from the fact that in FIG. 4b the bellows 24 is arranged co-axially within the tubular member 18.

In FIG. 4c the tubular member 18 extends downwards from a top wall of the chamber 10 and the mass or payload 14 is hanging or depending therefrom and connected thereto by means of the bellows 24. In this embodiment the gas pressure within the inner space 11 of the chamber 10 preferably substantially exceeds that of the inner space of the tubular member 18 so that the weight of the mass or payload 14 is at least partly balanced by the pressure difference between the inner space 11 of the chamber 10 and the inner space of the tubular member 18.

The embodiment shown in FIG. 4d mainly corresponds to that of FIG. 4c. However, in FIG. 4d the bellows 24 extends co-axially inside the tubular member 18.

It should be understood that the scope of the present invention is determined by the following claims and is in no way restricted by the embodiment described above merely as an example. Furthermore, the reference signs in the claims referring to the accompanying drawings shall not be construed as limiting the scope of protection.

1. A system comprising a chamber (10) defining a sealed inner space (11) and at least one vibration damper or isolator (15) for supporting a mass or payload (14) arranged within said space, said vibration damper comprising:
a hollow member (18) having an open inner end portion extending into the sealed space of the chamber,
a support structure (21) for supporting said mass,
a bellows (24) having its opposite ends sealingly connected to the hollow member and the support structure, respectively, so as to seal the inner space (26) of the hollow member from the inner space of the chamber, and
means (20) for exposing a surface part of the support structure to a gas pressure different from that of the sealed inner space of the chamber, so as to at least partly balance the weight of the support structure and said mass supported thereby.

2. A system according to claim 1, wherein the chamber contains gas at a sub atmospheric pressure.

3. A system according to claim 1, wherein the bellows is of a type allowing mutual movement of its opposite ends in the axial direction as well as a mutual translational movement in any radial direction of the bellows.

4. A system according to claim 1, wherein the bellows is of a type allowing restricted rotational movements around any radially extending axis in a cross-sectional plane of the bellows.

5. A system according to claim 1, wherein the support structure (21) comprises a base member (22) to which one end of the bellows is connected, and a mass supporting member (27), which is supported by the base member via spring members (28) allowing restricted rotational movement thereof in relation to the base member.

6. A system according to claim 5, wherein the spring members comprise leaf springs.

7. A system according to claim 1, further comprising an active electronic vibration isolating circuit (31, 34, 35) for assisting in counteracting vibrational movements of the support structure.

8. A system according to claim 7, wherein the electronic vibration isolating circuit comprises one or more actuators (31) and/or sensors (34, 35) arranged inside the hollow member.

9. A vibration isolator or damper for a system according to claim 1, said vibration damper comprising:
a hollow member (18) having an end portion for extending into the sealed space (11) of the chamber (10),
a support structure (21) arranged at said end portion of the hollow member for supporting said mass or payload (14), and
a bellows (24) having its opposite ends sealingly connected to the hollow member and the support structure, respectively.

10. A vibration isolator according to claim 9, wherein the bellows is of a type allowing mutual movement of its opposite ends in the axial direction as well as a mutual translational movement in any radial direction of the bellows.

11. A vibration isolator according to claim 9, wherein the bellows is of a type allowing restricted rotational movements around any radially extending axis in a cross-sectional plane of the bellows.

12. A vibration isolator according to claim 9, wherein the support structure comprises a base member (22) to which the bellows is connected, and an mass support member (27), which is supported by the base member via spring members (28) allowing restricted rotational movement thereof in relation to the base member.

13. A vibration isolator according to claim 12, wherein the spring members comprise leaf springs.

14. A vibration isolator according to claim 9, further comprising an active electronic vibration isolating circuit (31, 34, 35) for assisting in counteracting vibrational movements of the support structure.

15. A vibration isolator according to claim 14, wherein the electronic vibration isolating circuit comprises one or more actuators (31) and/or sensors (34, 35) arranged inside the hollow member.

16. A vibration isolator according to claim 9, wherein opposite abutment surfaces (22) defined by the support structure and by the hollow member, respectively, may co-operate so as to limit relative movement of the support structure.

17. A vibration isolator according to claim 9, wherein at least part of the length of the bellows extends along and adjacent to a length of a peripheral surface of the hollow member.

18. A vibration isolator according to claim 9, wherein the bellows is made from metal.
